(19) United States
(12) Patent Application Publication
(10) Pub. No.: US 2005/0225338 A1
(43) Pub. Date: Oct. 13, 2005

(54) Hard drive test fixture

(76) Inventors: Richard Lyle Sands, Rochester, MN (US); Donald John Wanek, Rochester, MN (US)

Correspondence Address: DORSEY & WHITNEY LLP;INTELLECTUAL PROPERTY DEPARTMENT, 50 SOUTH SIXTH STREET, MINNEAPOLIS, MN, 55402-1498, US

(21) Appl. No.: 11/086,781

(22) Filed: Mar. 22, 2005

Related U.S. Application Data
(60) Provisional application No. 60/557,873, filed on Mar. 31, 2004.

(51) Int. Cl. G01R 31/02

(52) U.S. Cl. 324/754

(57) ABSTRACT

The present invention is a method and apparatus for testing electrical or optical devices. The invention includes a test fixture having a top component, a first rail and a second rail coupled to the top component, and a connection component coupled to the first and second rails, wherein the test fixture is configured to receive 2.5 inch hard drives.

### CROSS-REFERENCE TO RELATED APPLICATION(S)

This application claims benefit under 35 U.S.C. § 119(e) to U.S. Provisional Patent Application Ser. No. 60/557,873, filed Mar. 31, 2004, entitled “Hard Drive Test Fixture”, the content of which is incorporated herein in their entirety for all purposes.

### FIELD OF THE INVENTION

The present invention relates generally to a fixture or carrier for securing and testing an electrical or optical device. In a specific example, the present invention relates to a fixture for securing and testing a hard drive.

### BACKGROUND OF THE INVENTION

A fixture or carrier is typically used in testing computer hard drives. The hard drives are generally subjected to a “burn-in” testing procedure and to thermal testing or environmental conditioning testing during the design and prototyping phases of the manufacturing process. The fixture or carrier is typically used to hold the drive while it undergoes the burn-in or final verification testing procedures. In addition, the fixture or carrier holding the drive may be placed in an environmentally-controlled test chamber for the testing procedures. These chambers are designed to expose the device under test to controlled temperature and humidity levels so that the drive manufacturer can obtain accurate performance test results over expected environmental ranges in which the devices are designed to operate. The tests can provide a valuable tool to verify product quality and reliability and to assure that the hard drives meet industry standards.

### BRIEF SUMMARY OF THE INVENTION

The present invention, in one embodiment, is a test fixture. The test fixture has a top component, a first rail and a second rail coupled to the top component, a connection component coupled to the first and second rails, and an insert component configured to be removably insertable into the test fixture.

The present invention, in another embodiment, is a test fixture. The test fixture has a first rail and a second rail, a connection component, and a first and second retention component. The first rail has a first receiving component and the second rail has a second receiving component. The connection component is removably coupleable with first and second receiving components. Further, the first and a second retention components are removably coupleable with the first and second receiving components, respectively, whereby the connection component is retainable in coupled connection with the first and second rails.

In a further embodiment, the present invention is a test pan. The test pan has a computer component coupled to the pan, a connector operably coupled to the computer component, and an interface controller component removeably coupled to the pan, wherein the interface controller component is operably and removably coupled to the connector.

The present invention, in yet another embodiment, is a method of testing a device. The method includes inserting an insert component into a fixture, inserting the device into the fixture; performing at least one test on the device; and removing the device from the test fixture. The fixture has a top component, a first rail and a second rail coupled to the top component, and a connection component coupled to the first and second rails.

While multiple embodiments are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 is a perspective view of a test fixture, according to one embodiment of the present invention.

FIG. 2 is a perspective view of a test fixture, according to another embodiment of the present invention.

FIG. 3A is a side view of a test fixture rail, according to one embodiment of the present invention.

FIG. 3B is a top view of a test fixture rail, according to one embodiment of the present invention.

FIG. 3C is a perspective view of a test fixture rail, according to one embodiment of the present invention.

FIG. 4A is a top view of a rail receiving component, according to one embodiment of the present invention.

FIG. 4B is a side view of a rail receiving component, according to one embodiment of the present invention.

FIG. 4C is an end view of a rail receiving component, according to one embodiment of the present invention.

FIG. 4D is a side view of a roller, according to one embodiment of the present invention.

FIG. 5 is a perspective view of an insert component for a test fixture, according to one embodiment of the present invention.

FIG. 6 is a perspective view of a test fixture and base component, according to one embodiment of the present invention.

FIG. 7 is a perspective view of two test fixtures and a base component in a stacked configuration, according to one embodiment of the present invention.

FIG. 8 is a perspective view of a pan, according to one embodiment of the present invention.

FIG. 9 is a perspective view of a portion of a pan, according to one embodiment of the present invention.

FIG. 10A is a side view of a portion of two test fixtures in a stacked configuration, according to one embodiment of the present invention.

FIG. 10B is a rear view of a portion of a test fixture, according to another embodiment of the present invention.

### DETAILED DESCRIPTION

The present invention relates to a test fixture configured to be adjustable to receive any one of several different kinds of 2.5 inch hard drives. Further, the present invention according to another embodiment is a stackable test fixture, such that two or more test fixtures can be stacked on top of each other, wherein two such stacked test fixtures occupy the same volume as one 3.5 inch hard drive test fixture. In addition, the present invention relates to a test fixture that is configured to receive 2.5 inch hard drives and is further configured to be used in test chambers designed to receive 3.5 inch hard drive test fixtures. The present invention can also be configured to receive 1.0 inch or 1.8 inch hard drives.

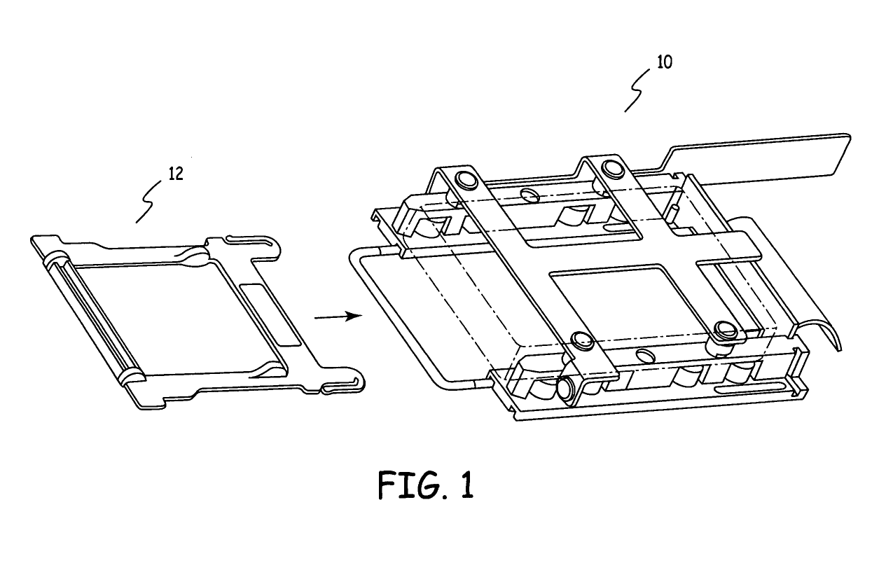

FIG. 1 shows a perspective view of a test fixture 10, according to one embodiment of the present invention. The fixture 10 is configured to support a hard drive during testing and is further configured to interface thereto. In one embodiment, the fixture 10 is configured to support a 2.5 inch hard drive during testing and interface thereto. Alternatively, the fixture 10 is configured to support other known electrical or optical devices for testing. According to one aspect of the present invention, the fixture 10 is configured for use within an environmental test chamber, as will be described in further detail below. Alternatively, the test fixture 10 is configured for use with any known stand, rack, storage cabinet or at any other known location for use of a test fixture.

According to one embodiment, the test fixture 10 is configured to receive an insert component 12. According to one embodiment, the insert component 12 allows for the variable compatibility of the test fixture 10 with several types of 2.5 inch hard drives. That is, the type of 2.5 inch hard drive that can be received by the test fixture 10 is determined, according to one embodiment, by the disposition of the insert component 12 within the fixture 10.

According to one embodiment, the insert component 12 can be inserted into the test fixture 10 as shown by the arrow in its depicted disposition. Alternatively, the insert component 12 can be inverted and inserted into the test fixture 10. Further, the test fixture 10 in one aspect of the present invention is configured to receive the insert component 12 such that the insert component 12 can be disposed within the test fixture 10 in at least two different locations.

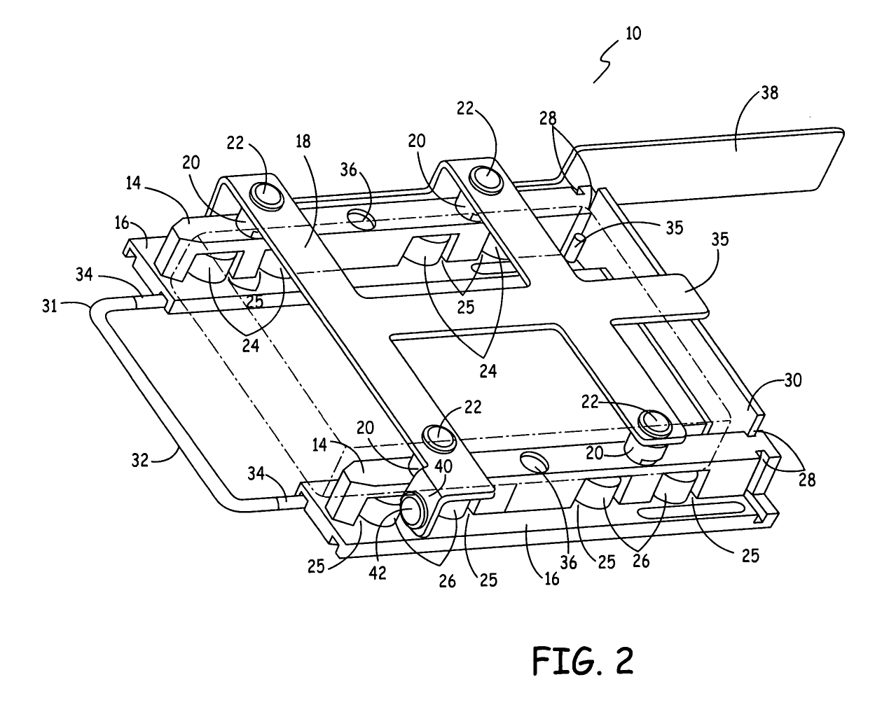

FIG. 2 depicts a perspective view of a test fixture 10, according to one embodiment of the invention. The test fixture 10 has two side components (also referred to herein as “rails”) 14 disposed on two rail receiving components (also referred to herein as “rail receiving plates”) 16. A top component (also referred to herein as a “top plate”) 18 is disposed above the rails 14. The rails 14, receiving plates 16, and top plate 18 are positioned to define a testing area configured to receive a device under test. One rail 14 has positioning rollers 24 disposed within recesses 25 defined by the rail 14 and the other rail 14 has pressure rollers 26 disposed within recesses 25 defined by the rail 14. Each rail 14 has slots 28 configured to position and support a connection component 30. The connection component 30 provides a connection between the device under test and the testing equipment, which shall be explained in further detail below. The fixture 10 according to one alternative embodiment has an ejection component 31 with an ejection handle 32 and two ejection rods 34 having contact components 35 at the ends of the rods 34 opposite the handle 32. Alternatively, the fixture 10 has no ejection component.

In use, a device to be tested can be inserted through the opening of the fixture 10 above the ejection handle 32 and into the testing area. According to one embodiment where the device is a hard disk drive, the fixture 10 is configured to allow for the drive to be positioned during insertion such that it can interface with the connection component 30 for testing purposes. According to a further embodiment, the fixture 10 is configured to also allow for the drive to be positioned in relation to the insert 12, which is appropriately positioned in the fixture 10 as described further herein to accommodate the drive. Alternatively, there is no insert 12 in the fixture 10. In a further alternative, the fixture 10 of the present invention is used to test other devices. In accordance with one aspect of the invention, the fixture 10 of the present invention containing a device to be tested is functional in either a horizontal or a vertical position.

The top component 18, in accordance with one aspect of the present invention, provides substantial rigidity and stability to the fixture 10, which can contribute to vibration dampening. According to one embodiment, the top plate 18 is disposed on spacer components (also referred to herein as “spacers”) 20 disposed above the rails 14 and fastened to the spacers 20 and rails 14 by fastening components 22 that, according to one embodiment, are screws. According to one alternative embodiment, the top plate 18 has a baffle component 38 configured to block air flow if the fixture 10 is placed in a test chamber. In an alternative aspect of the invention, the top component 18 has a protruding component or “finger” 33 that is configured to assist with retaining the connection component 30. In a further alternative, the top plate 18 has a tab 40 that, according to one embodiment, has an indicator 42 that, in one embodiment, is an LED indicator 42. The indicator 42 is configured to provide information. According to one embodiment, the indicator 42 could provide test status information, such as whether the test is complete, failed, busy, in progress, etc. Further, the indicator 42, according to an alternative aspect of the invention, could provide any relevant information.

According to one embodiment, the top component 18 is made of a non-magnetic stainless steel. Alternatively, the top component 18 is made of any known non-magnetic material that can provide substantial rigidity and stability to the fixture 10. In a further alternative, the top component 18 is configured in any structural configuration known to provide rigidity and stability, which can thereby contribute to vibration dampening.

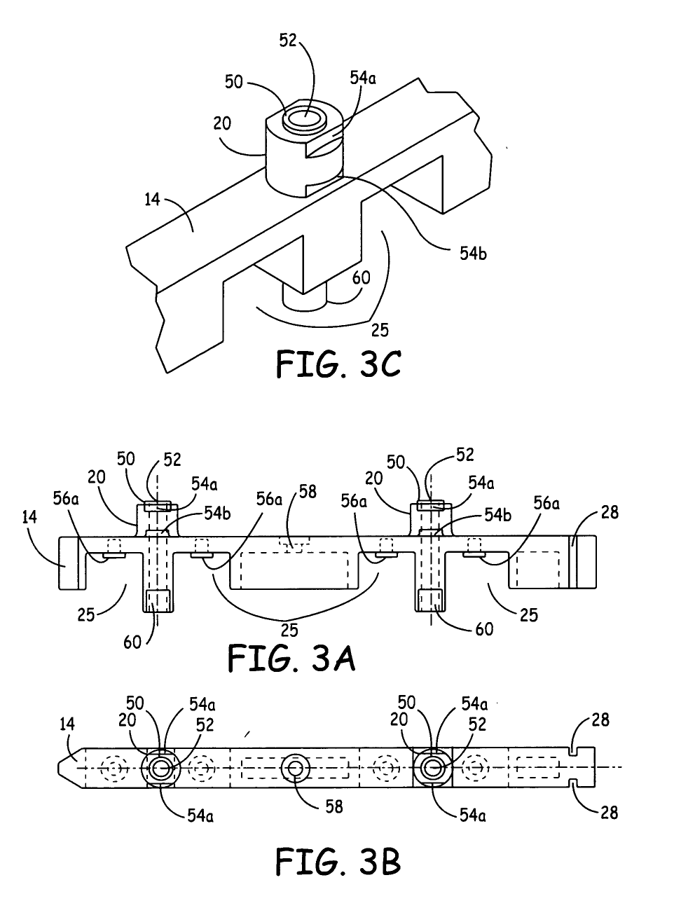

FIG. 3A is a side view of a rail 14, according to one embodiment of the present invention, and FIG. 3B is a top view of a rail 14, according to one embodiment of the present invention. Further, FIG. 3C is an expanded perspective view of a portion of a rail 14, according to one embodiment. The spacer components 20 are configured to provide space between the top of each rail 14 and the top component 18 that allows for air circulation over the top of a device under test in the fixture 10. Each spacer 20 has a positioning element 50 configured to position and align the top plate 18 and a hole 52 in the spacer that extends through the rail 14 and is configured to receive the fastening component 22 as shown in FIG. 2 that fastens the rail 14 to the rail receiving component 16. Alternatively, the rails 14 are attached to the rail receiving components 16 by any known attachment means.

Each spacer component 20 also has a top receiving portion 54a and a bottom receiving portion 54b. The top and bottom receiving portions 54a, 54b are configured to receive and position the insert component 12. The rail 14 also defines four recesses 25 configured to receive either positioning or pressure rollers 24, 26. Each recess has a top roller receiving component 56a configured to receive and position the roller. The rail 14 also has connection component slots 28 configured to assist with positioning and retaining the connection component 30. The rail 14 has a hole 58 configured to receive the fastening component 36 as shown in FIG. 2, which, according to one embodiment, secures the rail 14 to the rail receiving component 16. According to one embodiment, each fastening component 36 is a self-threading screw. Alternatively, the fastening components 36 can be any known fastening means. Further, the rail 14 has alignment components 60 projecting from a bottom portion of the rail 14. According to one embodiment, the rail 14 has two alignment components 60. Alternatively, the two alignment components 60 are configured to be inserted into two alignment receiving components 72, which are defined by the rail receiving plate 16 and configured to receive the alignment components 60.

According to one embodiment, each rail 14 is configured identically such that each one is universally interchangeable with any other. Alternatively, each rail 14 is not identical.

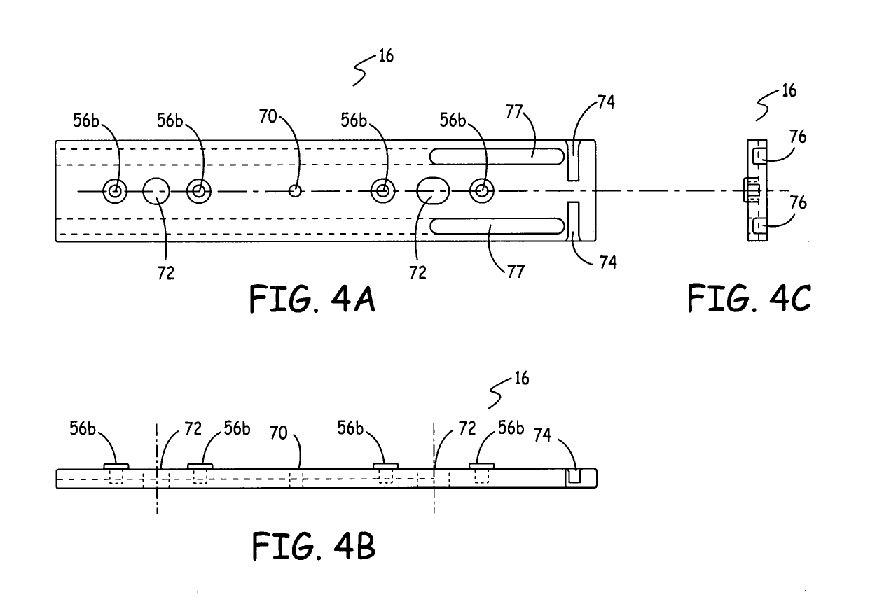

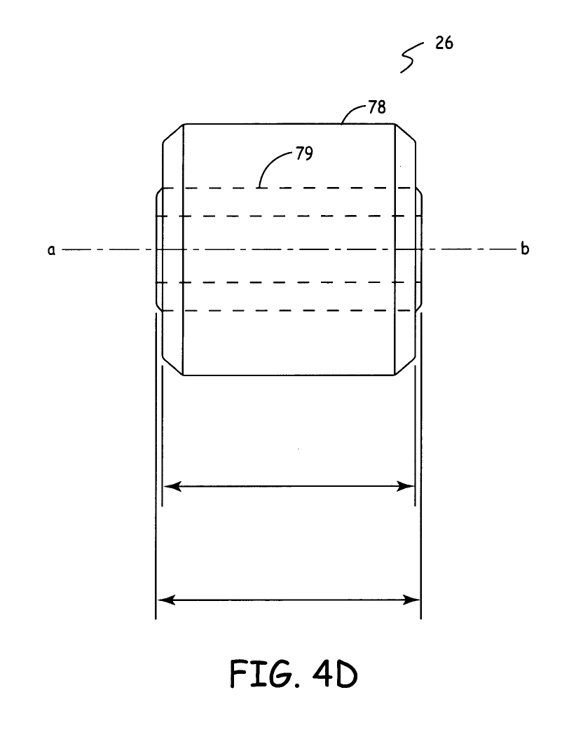

FIG. 4A is a top view of a rail receiving component 16, according to one embodiment of the present invention, and FIG. 4B is a side view of a rail receiving component 16, according to one embodiment of the present invention. Further, FIG. 4C is an end view of a rail receiving component 16, according to one embodiment of the present invention. The rail receiving component 16, according to one embodiment, defines a hole 70 configured to receive the fastening component 36 as depicted, for example, in FIG. 2, and further defines four bottom roller receiving components 56b configured to function in cooperation with the top roller receiving components 56a as depicted, for example, in FIG. 3A, to receive and position the rollers. In addition, the rail receiving component 16, according to one embodiment, defines two alignment receiving holes 72 configured to receive the alignment components 60 that protrude from the bottom of the rail 14 as shown, for example, in FIGS. 3A and 3C, wherein the alignment components 60 and receiving holes 72 function together to align the rail 14 and the rail receiving component 16. The component 16 also defines a connection component slot 74 configured to receive and assist in aligning the connection component 30, as shown in FIG. 2. In accordance with one alternative embodiment, the component 16 defines two ejection rod slots 76 on the bottom side of the component 16 and two contact component slots 77 on the top side of the component 16. The ejection rod slots 76 are configured to receive the ejection rods 34 and the contact component slots 77 are configured to receive the contact components 35 and allow the contact components 35 to move along the slots 77. Alternatively, each rail receiving component 16 defines one ejection rod slot 76 and one contact component slot 77. In a further alternative, the rail receiving component 16 does not have an ejection rod slot or contact component slot.

Each rail 14 and rail receiving component 16, according to one embodiment, is made of a lubricative, injection-molded, electrically dissipative and vibration-damping composite material. For example, according to one embodiment, each rail 14 is made of RTP387 TFE 10, which is a carbon fiber filled polytetrafluoroethylene polycarbonate manufactured by RTP Company in Winona, Minn. Alternatively, each rail 14 and rail receiving component 16 is made of any known material having suitable electrical dissipation and vibration damping characteristics for hard drive testing.

According to one embodiment, the rollers 24, 26 as shown in FIG. 2 cooperate with the rails 14 to guide and position a device to be tested within the fixture 10. According to one embodiment, the positioning rollers 24 function to contact and align the device to be tested such that connection points on the device are aligned with the appropriate corresponding connection points on the connection component 30. Further, the pressure rollers 26 are configured to contact and urge the device downward against the receiving plate 16 and against the opposing positioning rollers 24. The relatively rigid positioning of the device, along with the limited float allowed the connection component 30 in the slots 28, assures accurate and repeatable connection between the device and the testing electronics. The fixture 10 is configured such that the left rail 14 has two positioning rollers 24 and the right rail 14 has two pressure rollers 26. Accordingly, when the drive to be tested is inserted into the fixture 10, it is contacted by the two positioning rollers 24 in the left rail 14 and by the two pressure rollers 26 in the right rail 14. Alternatively, the fixture 10 is configured such that the left rail 14 has two pressure rollers 26 and the right rail 14 has two positioning rollers 24. Alternatively, the fixture 10 has any known type of rollers 24, 26.

According to one embodiment, the rollers 24, 26 protrude somewhat from each rail 14 into the test area of the fixture 10. The positioning rollers 24, in accordance with one aspect of the invention, protrude from about 10 mils to about 30 mils from the rail 14. In a further embodiment, the pressure rollers 26 protrude from about 50 mils to about 100 mils from the rail 14. Alternatively, the rollers 24, 26 can be spring biased.

According to one embodiment, the top and bottom roller receiving components 56a, 56b, as shown, for example, in FIGS. 3A, 4A, and 4B, are configured to retain the rollers 24, 26 in a fixed manner and to tilt the rollers 24, 26 inward toward the connection component 30. That is, the top portion of each roller 24, 26 is slightly closer to the connection component 30 than the bottom portion of each roller 24, 26. In one aspect of the invention, the top and bottom receiving components 56a, 56b tilt the rollers 24, 26 such that a longitudinal axis on which each roller rotates from a perpendicular position at an angle from about 1 degree to about 10 degrees. The tilt facilitates positioning of the device under test. According to one embodiment, the tilt provides a downward force that urges the inserted device onto the rail receiving component 16 for alignment purposes. Alternatively, the longitudinal axes of the rollers 24, 26 are perpendicular to the plane of the rail receiving component 16.

According to one embodiment in which the device under test is a hard drive, the rollers 24, 26 are configured to contact the hard drive only at the mounting screw locations on the hard drive. Given that 2.5 inch hard drives typically have only two mounting screw locations on each side, only two rollers 24, 26 need be disposed within each of the rails 14 in such an embodiment. That is, only two positioning rollers 24 are needed in one rail 14, and only two pressure rollers 26 are needed in the other rail 14. Further, the location of the rollers 24, 26 in the rails 14 according to this embodiment are determined by the location of the mounting screw locations. As such, the positioning rollers 24 may be disposed within the two inner recesses 25 or the two outer recesses 25 of the rail 14, depending on the mounting screw locations. Similarly, the pressure rollers 26 may be disposed within the two inner recesses 25 or the two outer recesses 25 of the rail 14, depending on the mounting screw locations. Alternatively, the rollers 24, 26 are positioned in any fashion that allows the rollers 24, 26 to receive and position the device to be tested in the fixture 10.

In accordance with one aspect of the invention, the positioning rollers 24 are hard and the pressure rollers 26 are soft. That is, each positioning roller 24 is fabricated of an acetal copolymer or an equivalent polymer with similar dissipative and hardness characteristics. For example, according to one embodiment, the rollers 24 are fabricated of Pomalux SD-A®, which is available from Westlake Plastics Co. in Lenni, Pa. Alternatively, each positioning roller 24 is made up of any known hard material. In a further alternative, each positioning roller 24 is made up of any known material used for rollers in test fixtures.

FIG. 4D shows an elevated view of a pressure roller 26 having an outer sleeve 78 and a core 79. In this embodiment, the line a-b depicts the longitudinal axis of the roller 26. The outer sleeve is made up a known soft material. According to one embodiment, the outer sleeve 78 of the pressure roller 26 is cast of a soft, rubbery elastomeric compound surrounding a central hard core 79. For example, the outer sleeve 78 can be made of K-Prene®, a urethane elastomer available from Acrotech, Inc. of Lake City, Minn. In a further example, the outer sleeve 78 can be made of ethylene propylene diene monomer (“EPDM”), a material available from 7-Sigma of Minneapolis, Minn. Alternatively, the outer sleeve 78 is any known soft material that can be used on the roller 26. The hard core 79 comprises a known hard material such as, for example, brass, stainless steel, or hard plastic. In a further alternative, each pressure roller 26 is made up of any known material used for rollers in test fixtures.

The connection component 30 (also referred to as an “interposer”) as best shown in FIG. 2, in accordance with one aspect of the invention, is a component that provides a two-way connection between a connector on the device under test and the testing equipment (not shown) that controls the test protocols during testing. The testing equipment may include such equipment as a test driver, data collection equipment, circuitry, and a power source. According to one embodiment, the connection component 30 is a test card commonly used for testing hard drives. The connection component 30, in accordance with one embodiment, is positioned at a rear portion of the fixture 10 by any known means.

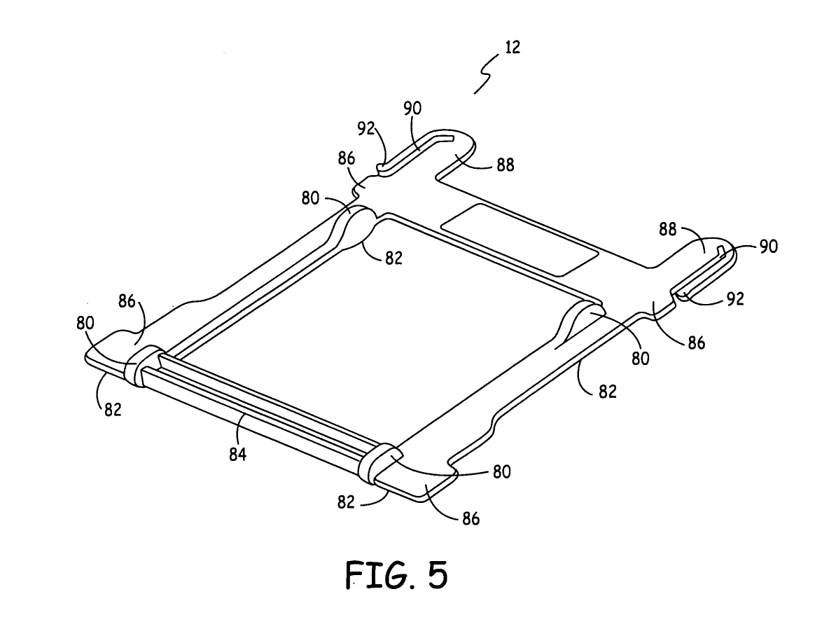

FIG. 5 is a perspective view of an insert component 12, according to one embodiment of the present invention. The component 12 has four upper projections 80 and four lower projections 82. According to one embodiment, the upper projections 80 are larger than the lower projections 82. Alternatively, the upper projections 80 and lower projections 82 are relatively the same size. In a further alternative, the lower projections 82 are larger than the upper projections 80. In yet another alternative, the insert component 12 has no projections. In accordance with one embodiment, the insert component 12 has a handle 84 and four extended flat portions or “tabs” 86. In addition, the insert 12 according to one embodiment has two releasable retention components 88 configured to assist in maintaining the position of the insert component 12 once it has been inserted into the fixture 10. According to one embodiment, the releasable retention components 88 each have an arm component 90 and a contact component or “catch” 92. According to one embodiment, the distance across the insert 12 between the outer edge of each catch 92 is greater than the distance between the spacers 20 on opposing rails 14 in a fixture 10 as shown in FIG. 2 such that the catches 92 must contact and be forced toward the center of the insert 12 in order to move past the spacers 20 during insertion. Alternatively, the release retention components 88 are any component providing a mechanism for releasably maintaining the position of the insert 12 within the fixture 10. According to one embodiment, the insert 12 is fabricated of a molded, electrically dissipative, and lubricious material. For example, in one embodiment, the material is Pomalux SD-A®. In a further alternative, the insert 12 is fabricated of any known material for use in a hard drive testing device.

The insert 12 is configured to be inserted into the fixture 10 in several different positions, thereby allowing for different types or thicknesses of 2.5 inch hard drives to be inserted into the fixture 10. According to one embodiment, the insert 12 can be inserted as depicted in FIG. 1, wherein the upper projections 80 are facing upward. Alternatively, the insert 12 can be inserted with the lower projections 82 facing upward. In accordance with one aspect of the invention, the insert 12 can be positioned during insertion such that each of the four tabs 86 are positioned to contact or rest on top of the top receiving portions 54a of each spacer component 20 of the fixture 10 as best shown, for example, in FIGS. 2, 3A, and 3C. Alternatively, the insert 12 can be positioned during insertion such that the tabs 86 are positioned in contact with or beneath the bottom receiving portions 54b of each spacer component 20.

In use, the insert 12 is inserted into the testing area of the fixture 10 with the appropriate projections facing in the desired direction and the tabs 86 positioned in the fixture 10 as desired. As the insert 12 is inserted into the fixture 10, the catch 92 on each side of the insert 12 is moved past the spacers 20 closest to the connection component 30. As they move past the spacers 20, the catches 92 make contact with the spacers 20 and are pushed inward by the spacers 20 such that when they move to the back of the spacers 20 (toward the connection component 30), the catches 92 spring outward to their untensioned positions. In this position, the tabs 86 contact the spacers 20 as described above. As a result, the release retention components 88 provide a retention function that maintains the position of the insert 12 in the fixture 10 but can be overcome by lightly pulling on the handle 84 of the insert 12 in a direction away from the connection component 30.

According to one embodiment, each variation in the disposition of the projections 80, 82 and in the position of the insert 12 within the fixture 10 provides for accommodating a different type of hard drive. For example, in accordance with one aspect of the invention in which the projections 80 are larger than the projections 82, if the insert 12 is inserted with the upper projections 80 facing upward and the insert 12 positioned such that the tabs 86 are positioned in contact with the top receiving portions 54a of the spacers 20, the fixture 10 can, according to one embodiment, accommodate a 15 mm thick hard drive. If the same insert 12 is inserted with the upper projections 80 facing upward and the insert 12 positioned such that the tabs 86 are positioned in contact with the bottom receiving portions 54b of the spacers 20, the fixture 10 can accommodate a 9.5 mm thick hard drive. In one embodiment using the same insert 12, if the insert 12 is inserted with the upper projections 80 facing downward and the insert 12 positioned such that the tabs 86 are positioned in contact with the top receiving portions 54a of the spacers 20, the fixture 10 can accommodate a 12.5 mm thick hard drive. In a further embodiment, if the same insert 12 is inserted with the upper projections 80 facing downward and the insert 12 positioned such that the tabs 86 are positioned in contact with the bottom receiving portions 54b of the spacers 20, the fixture can accommodate a 7 mm thick hard drive. Alternatively, if no insert 12 is placed in the fixture 10, the fixture can accommodate a 17 mm thick hard drive.

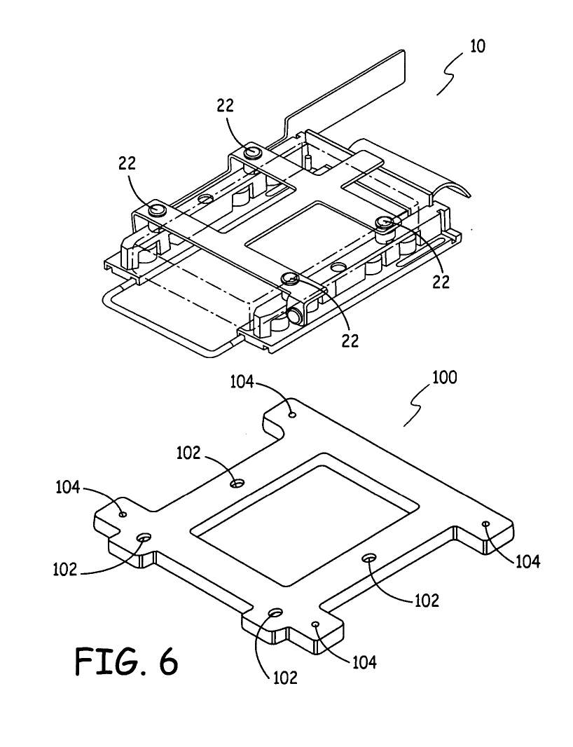

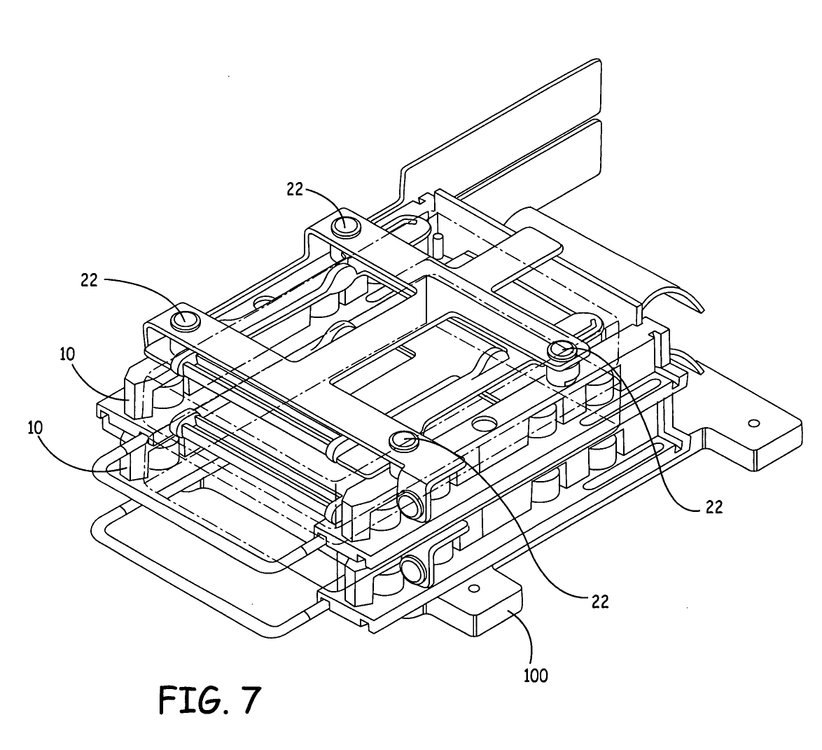

FIG. 6 is a perspective view of a base component 100, according to one embodiment of the present invention. According to one embodiment, the fixture 10 is disposed on the base component 100 and connected to the base component 100 by the fastening components 22 that also fasten the top component 18 to the rails 14. The fastening components 22 are received in the base component 100 at holes 102. The base component 100 also defines holes 104, which are configured to allow fasteners to be inserted into the holes 104 for fastening the base component to another object (not shown) as will be further explained below. According to one embodiment, the base component 100 is fabricated of a composite material. For example, the base component 100 in one embodiment is RTP387 TFE 10. Alternatively, the base component 100 is fabricated of any known material used in hard drive testing devices. In an alternative embodiment shown in FIG. 7, two fixtures 10 can be stacked on top of the base component 100, wherein the fastening components 22 run through the holes 52 in the spacers 20 and rails 14 of both the stacked fixtures 10 as best shown in FIGS. 3A and 3B, and are inserted into the holes 102 in the base component 100.

According to one alternative embodiment, the ejection component 31 as best depicted in FIG. 2 is configured to disconnect the tested device from the connection component 30 and facilitate removal of the device. The ejection handle 32 and ejection rods 34 can be made of any known material used in test fixtures. According to one embodiment, the handle 32 and rods 34 are made of non-magnetic stainless steel. In a further embodiment, the ejection handle 32 is covered in a soft material, which, according to one embodiment, is rubber. The contact components 35, also referred to as “ejection bumpers,” can consist of a soft material on the outer surface of the contact components 35 that will not damage the device being tested when it is contacted by the contact components 35. According to one embodiment, the ejection bumpers 35 have a rubber outer surface.

In operation, a device under test in the fixture 10 is removed by a user pulling on the handle 32. The movement of the handle 32 away from the fixture 10 causes the rods 34 and the ejection bumpers 35 to move in the same direction, thereby contacting the device in the fixture 10 and urging the device out of the fixture 10. According to one embodiment, the configuration of the ejection component 31 with two bumpers 35 allows for even pressure on the device being ejected by the ejection bumpers 35, thereby assuring that the device will be ejected out of the fixture 10 without contacting portions of the fixture 10 and causing damage to the device. Because the ejection component 31 has no return mechanism, the component 31 remains in an extended or “ejected” position wherein the handle 32 is at its most extended position away from the fixture 10. In this position, the handle 32 can act as a guide component for a new device to be tested. That is, the handle 32 and rods 34 extending out from the fixture 10 can be used to position or support and direct the device into the appropriate disposition as it is inserted into the fixture 10. In this embodiment, the handle 32 is then urged back toward the fixture 10 as the device to be tested is urged into the fixture 10.

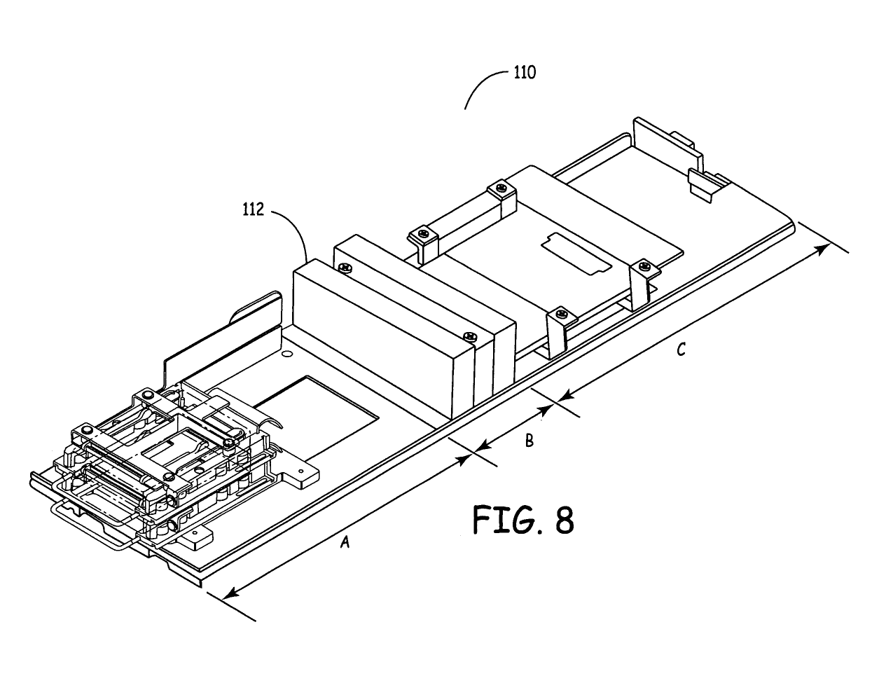

FIG. 8 depicts a perspective view of a pan 110 that can be placed in a test chamber, according to one embodiment of the present invention. The pan 110 is also referred to as a pallet or shelf. The pan 110 used in conjunction with a test chamber provides an efficient way to test a fixture in a climate-controlled environment. Area A of the pan is configured to receive a test fixture such as the test fixture 10 of the present invention. Area C is configured to receive the electronic testing equipment used to test the hard drive. Area B comprises the insulating brick wall that separates areas A and C. According to one embodiment, the brick wall of area B forms a hot air purged plenum. The brick wall and plenum, when the pan 110 is used in conjunction with a test chamber, forms a climate barrier that allows for separate environments in areas A and C. According to one embodiment, the conditions created in area C are those best suited for optimal operation of the test electronics while allowing for conditions in area A in which the temperature and humidity can be varied within a test range required to test the hard drive or device being tested.

According to one embodiment of the present invention, the test fixture 10 and base component 100 of the present invention can be mounted to area A of the pan 110. The fixture 10 and base component 100 are mounted to the pan 110 by fastening components (not shown) inserted through holes 104 in the base component 100 and into holes (not shown) in the pan 110. Alternatively, the base component 100 is connected to the pan 110 by any known fastening means.

According to one embodiment, if the fixture 10 is placed on a pan 110 configured for receiving 3.5 inch hard drive test fixtures, the baffle 38 on the top component 18 as best shown in FIG. 2 is configured to block airflow between the connection component 30 and an insulating wall 112 shown in area B in FIG. 8. According to one embodiment, this blocking action by the baffle 38 enhances air flow around the device.

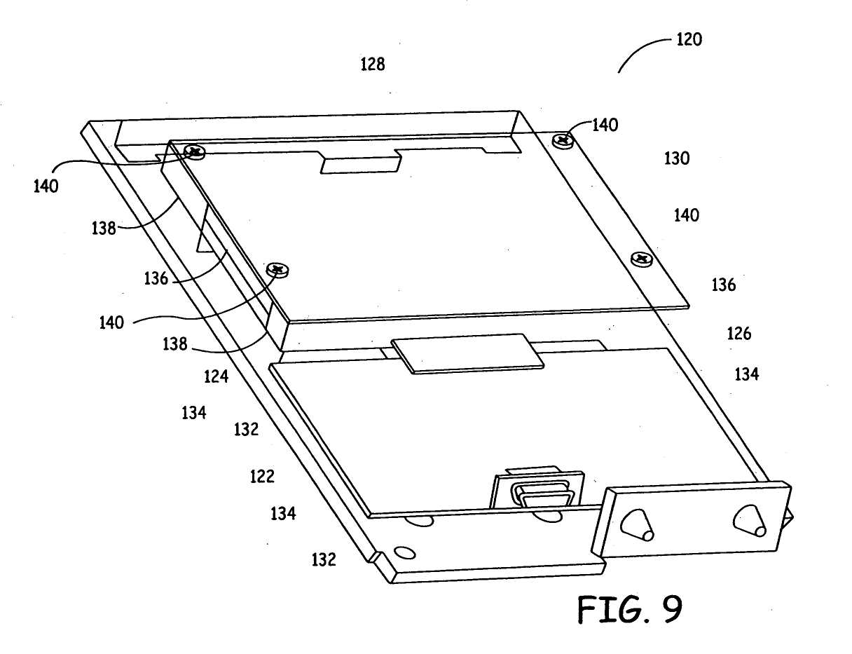

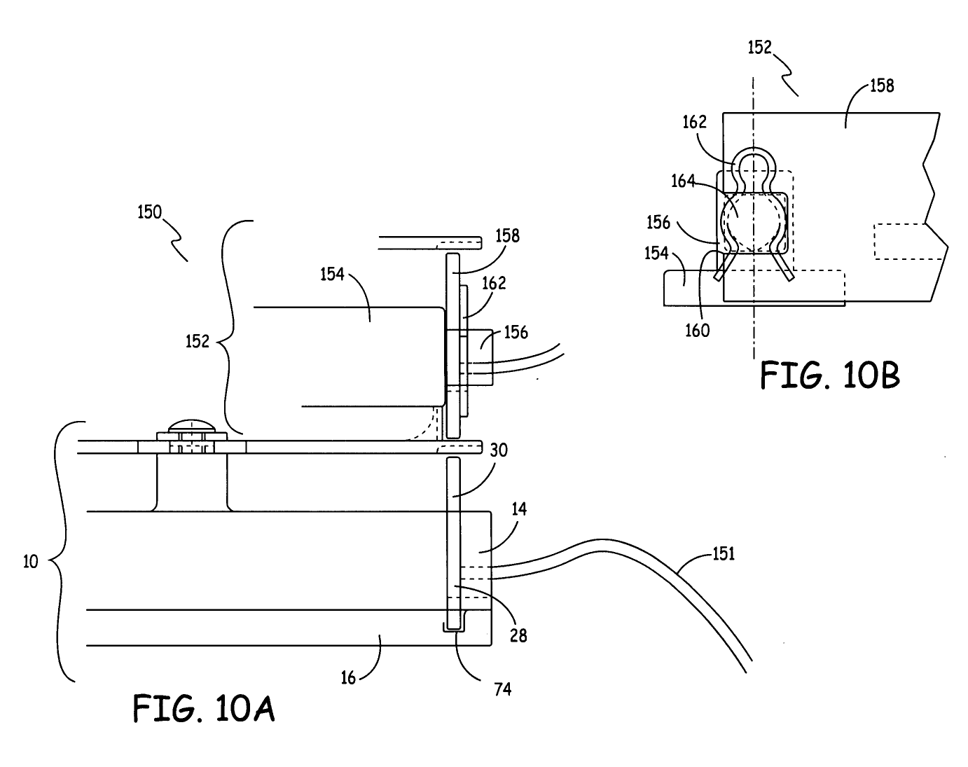

In an alternative embodiment, the present invention is a test pan and a fixture allowing for fast and simple replacement of various components. FIG. 9 shows a portion of a pan 120 configured to support testing electronics, according to one embodiment of the present invention. The portion of the pan 120 depicted in FIG. 9 is generally equivalent in one embodiment to area C in FIG. 8. The pan 120 has a computer component 122 operably coupled to an interface controller component 124 by a connector 126. The interface controller component 124 is operably coupled ultimately to the connection component 30 of the test fixture 10 as best depicted for exemplary purposes in FIG. 2 via a cable connector 128, which is operably coupled in turn to the connection component 30 according to one embodiment via a cable 151 as best shown in FIG. 10A. The pan 120 also has a power component 130 that can be operably coupled to the controller component 124 or, alternatively, to the cable connector 128.

The computer component 122 is a known component configured to control the testing of the device, such as a hard drive, being tested, and according to one embodiment is a single board computer (“SBC”). The computer component 122, according to one embodiment, is disposed on the pan 120 by four support components 132 and fastened to the support components 132 and pan 120 by fastening components 134.

The interface controller component 124 is a known component configured to receive instructions from the computer component 122 via the connector 126, translate the instructions and transmit the instructions via the cable connector 128 and the connection component 30 to the hard drive being tested. According to one embodiment, the interface controller component 124 is an interface controller board. In one example, the interface controller board is an industry standard hard drive interface such as SCSI, SATA-1, SATA-2, SATA-3, SAS, U320, USB, or FCAL interface, or any other known interface. According to one embodiment, the interface controller component 124 is slideably and removably disposed on the pan 120 in slots 136 that are connected to support components 138.

According to one embodiment, the connector 126 is a known high speed connector. In one example, the connector 126 is a standard PCI-Express.

The power component 130, according to one embodiment, is configured to supply electrical power to the hard drive under test via the cable connector 128. According to one embodiment, the power component 130 is a margin or voltage component 130 and may also be referred to herein as a “power card” or “margin card.” The power component 130, in one aspect of the invention, is disposed above the interface controller component 124 on top of the support components 138 and attached to the support components 138 by the fastening components 140.

The pan 120 is configured to allow for quick and easy removal and replacement of various components. According to one embodiment, the interface controller component 124 and associated cables and connectors can be quickly and easily removed from the pan 120 and replaced. For example, the interface controller component 124 can be removed and replaced in the following fashion, according to one embodiment of the present invention. First, the pan 120 is removed from the test chamber. Then the insulating brick wall (not shown) of the pan 120 (equivalent to the brick wall shown in area A of FIG. 8) is removed. In FIG. 9, the brick wall is located just beyond and adjacent to the depicted portion of the pan showing the cable connector 128. Once the wall is removed, the interface controller component 124 can be removed from the pan 120 by pulling the component 124 in a direction away from the computer component 122 such that it slides out along the slots 48. According to one embodiment, cables and connectors or any other related components (not shown) associated with the interface controller component 124 may need to be removed from the pan 120 as well. Once it is removed, another controller component 124 can be inserted by sliding the component 124 along the slots 48 in a direction toward the computer component 122. In one embodiment, appropriate cables and connectors or other components are also added.

The present invention, according to an alternative embodiment, includes a test fixture configured to allow for quick and easy connection component 30 removal and replacement. That is, the connection component 30 can be easily removed from the fixture 10 and disconnected from the cable connector 128. FIG. 10A depicts a side view of the rear portion of two test fixtures in a stacked configuration 150, according to one embodiment of the present invention. The top test fixture 152 is the novel fixture 152 providing for easy connection component removal and replacement. For purposes of comparison, the bottom test fixture 10 is the fixture 10 disclosed above and depicted in FIG. 2. FIG. 10B depicts a rear view of a portion of the test fixture 152, according to one embodiment of the present invention.

Alternatively, the interface controller component 124 and the connection component 30 at the test fixture 10 are both quickly and easily removed and replaced. In this embodiment, the interface controller component 124 is unique to the connection component 30 such that if the connection component 30 is removed and replaced, the interface controller component 124 must be replaced with an interface controller component 124 compatible with the new connection component 30.

In a further alternative, the interface component 124, the connector 128, the cable 151, and the connection component 30 are removed and replaced as a unit. In yet another alternative, any of these components, including the computer component 122, the power component 130, or any other known associated components, can be individually, or in any combination, removed and replaced with ease.

According to one alternative embodiment, the test fixture 152 as shown in FIGS. 10A and 10B has rails 154 with a modified end. That is, in contrast to each rail 16 of fixture 10, which has a slot 74 configured to receive the connection component 30, each rail 154 of fixture 152 has an interface receiving component 156 configured to receive the connection component 158. According to one embodiment, the interface receiving component 156 is a protruding component 156. The connection component 158 has a notch 160 at each end that fits over the protruding component 156 such that the protruding component 156 supports and maintains the position of the connection component 158. The position of the connection component 158 on the protruding component 156 is further maintained with a retention component 162 that is, according to one embodiment, a clamp pin. The clamp pin 162 slips into a groove 164 molded or formed in any fashion into the protruding component 156. The groove 164 is best shown by the broken line in FIG. 10B. Alternatively, the interface receiving component 156 can be any mechanism or apparatus for retaining the connection component 30 in a fashion that allows for fast and easy removal and replacement.

In use, a connection component 158 as shown in FIGS. 10A and 10B can be removed or replaced quickly and easily in the following fashion, according to one embodiment of the present invention. First, the retention component 162 is removed from the protruding component 156. The connection component 158 can then be easily removed by sliding the component 158 off the protruding component 156 at the notches 160 on the connection component 158.

Subsequently, another connection component 158 can be placed over the protruding components 156 and fastened into position by sliding the retention component 162 over the groove 164 in the protruding component 156.

Although the present invention has been described with reference to preferred embodiments, persons skilled in the art will recognize that changes may be made in form and detail without departing from the spirit and scope of the invention.

1. A test fixture comprising:
(a) a top component;
(b) a first rail and a second rail coupled to the top component;
(c) a connection component removably coupled to the first and second rails; and
(d) an insert component configured to be removably insertable into the test fixture.

2. The test fixture of claim 1 wherein the test fixture is configured to receive 2.5 inch hard drives of variable dimensions.

3. The test fixture of claim 1 wherein the test fixture is stackable.

4. The test fixture of claim 1 further comprising at least one roller disposed within a recess in each of the first and second rails.

5. The fixture of claim 1 further comprising a first rail receiving component and a second rail receiving component coupled to the first and second rails, respectively.

6. The fixture of claim 5 further comprising a base component coupled to the first and second rail receiving components.

7. The fixture of claim 1 further comprising an ejection mechanism coupled to the fixture, the ejection mechanism comprising two rods selectively extendable through apertures in the first and second rail receiving components.

8. The fixture of claim 1 wherein the connection component is configured to interface with a device to be tested.

9. The fixture of claim 1, wherein the first rail comprises a first slot and the second rail comprises a second slot, wherein each of the first and second slots are configured to receive the connection component.

10. The fixture of claim 1, wherein the first rail comprises a first receiving component and the second rail comprises a second receiving component, wherein each of the first and second receiving components are configured to receive the connection component.

11. The fixture of claim 10, wherein the first and second receiving components are configured to receive a first and second retention component, respectively, whereby the connection component is removably retainable in coupled connection with the first and second rails.

12. A test pan comprising:
(a) a computer component coupled to the pan;
(b) a connector operably coupled to the computer component; and
(c) an interface controller component removeably coupled to the pan, wherein the interface controller component is operably and removably coupled to the connector.

13. The test pan of claim 12, wherein the computer component is removably coupled to the pan and operably and removably coupled to the connector.

14. The test pan of claim 12, further comprising a power component coupled to the connector.

15. The test pan of claim 14, wherein the power component is operably and removably coupled to the connector.

16. The test pan of claim 12, wherein the interface controller component is operably connected to a connection component of a test fixture via a cable, wherein the interface controller component and the connection component are configured to be substantially simultaneously removable.

17. The test pan of claim 16 wherein the interface controller component, the connector, the connection component, and the cable are configured to be substantially simultaneously removable.

18. A method of testing a device comprising:
inserting a insert component into a fixture comprising:
a top component;
a first rail and a second rail coupled to the top component; and
a connection component coupled to the first and second rails; and
inserting the device into the fixture;
performing at least one test on the device; and
removing the device from the test fixture.
